(19) United States
(12) Patent Application Publication
(10) Pub. No.: US 2021/0035644 A1
(43) Pub. Date: Feb. 4, 2021

(54) MEMORY APPARATUS AND DATA ACCESS METHOD FOR MEMORY

(71) Applicant: Macronix International Co., Ltd., Hsinchu (TW)

(72) Inventors: WEI-CHIH CHIEN, New Taipei City (TW); Hsin-Yi Ho, Hsinchu City (TW); Hsiang-Lan Lung, Kaohsiung City (TW)

(73) Assignee: Macronix International Co., Ltd., Hsinchu (TW)

(21) Appl. No.: 16/529,553

(22) Filed: Aug. 1, 2019

(51) Int. Cl. G11C 16/16; G11C 16/26; G11C 16/34

(52) U.S. Cl. CPC G11C 16/16; G11C 16/3436; G11C 16/26

(57) ABSTRACT

A memory apparatus and a data access method for a memory are provided. The data access method includes: receiving a data erase command for performing a data erase operation; and, during the data erase operation: configuring a selected memory cell block in the memory according to the data erase command; providing a flag memory cell corresponding to the selected memory cell block, erasing a data in the flag memory cell according to the data erase command, and keeping a data in a plurality of selected memory cells in the selected memory cell block unchanged.

### BACKGROUND OF THE INVENTION

### Field of the Invention

The invention relates to a memory apparatus and a data access method for a memory, and more particularly, to a memory apparatus capable of increasing speed and a data access method for a memory.

### Description of Related Art

With the advancement of electronic technology, electronic products have become an important tool in everyday life. In an electronic apparatus, the access speed of the memory apparatus therein may affect the response speed of the electronic apparatus. Referring to FIG. 1 and FIG. 2, FIG. 1 shows a circuit diagram of a memory cell of the prior art, and FIG. 2 shows a graph of the relationship between access speed and temperature of a non-volatile memory. A memory cell 100 shown in FIG. 1 is a non-volatile memory cell (e.g., a resistive memory cell, a flash memory cell, or a phase change memory cell). The memory cell 100 includes a transistor T1 and a phase change material layer PCL. The transistor T1 and the phase change material layer PCL are sequentially connected in series to a ground voltage GND and a bit line BL. The control terminal of the transistor T1 is coupled to a word line WL and is turned on according to the signal on the word line WL.

When a data access operation is performed on the memory cell 100, a reset operation, a set operation, or a read operation may be performed for the memory cell 100 by applying a bias voltage to the phase change material layer PCL. In particular, the reset and set operations are used to change the resistance value provided by the phase change material layer PCL. In FIG. 2, curve RP indicates that when a reset operation is performed on the memory cell 100, the temperature of the phase change material layer PCL needs to be higher than a melting temperature Tₘₑₗₜ and a first time interval needs to be maintained to melt the crystals of the phase change material layer PCL and complete the reset operation. Curve SP indicates that when a set operation is performed on the memory cell 100, the temperature of the phase change material layer PCL needs to be higher than a crystallization temperature T_{crystal} (below the melting temperature Tₘₑₗₜ) and a second time interval needs to be maintained so that the crystals of the phase change material layer PCL are crystallized and the set operation is completed. Curve READ indicates a read operation is performed for the memory cell 100 and shows the relationship between temperature and operation time of the memory cell 100. The second time interval is greater than the first time interval.

In any case, as may be seen from FIG. 2, it takes a fixed time to perform a reset operation and a set operation for the memory cell 100. Therefore, when a write operation is performed for the memory cell 100, it takes a relatively long time to reduce the access speed of the memory cell 100.

### SUMMARY OF THE INVENTION

The invention provides a memory apparatus and a data access method for a memory, which may effectively improve the erase speed of a memory cell.

The data access method for a memory of the invention includes the following steps.

A data erase command is received for performing a data erase operation. During the data erase operation: a selected memory cell block in the memory is set according to the data erase command, a flag memory cell corresponding to the selected memory cell block is provided, a data in the flag memory cell is erased according to the data erase command, and a data in a plurality of selected memory cells in the selected memory cell block is kept unchanged.

The memory apparatus of the invention includes a plurality of memory cell blocks, a plurality of flag memory cells, and a controller. The flag memory cells respectively correspond to the memory cell blocks. The controller is coupled to the memory cell blocks and the flag memory cells and set to receive a data erase command to perform a data erase operation; and, during the data erase operation, a selected memory cell block in the memory cell blocks is set according to the data erase command; and, according to the data erase command, a data in the flag memory cell corresponding to the selected memory cell block is erased, and a data in the plurality of selected memory cells in the selected memory cell block is kept unchanged.

Based on the above, in the invention, when the data erase operation for the selected memory cell block is performed, the erase operation is performed only for the flag memory cell corresponding to the selected memory cell block, and a physical data erase operation is not performed for the selected memory cell in the selected memory cell block. In this way, the time required for the data erase operation may be greatly reduced, the power consumed may be reduced, and the overall effect of the memory may be improved.

It is to be understood that both the foregoing general description and the following detailed description are exemplary, and are not intended to limit the scope of the invention.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 shows a circuit diagram of a memory cell of the prior art.

FIG. 2 shows a graph of the relationship between access rate and temperature of a non-volatile memory.

FIG. 3 shows a flowchart of a data access method for a memory of an embodiment of the invention.

FIG. 4 shows a flowchart of a data access method for a memory of another embodiment of the invention.

FIG. 5 shows a schematic of an operation of a data access method of an embodiment of the invention.

FIG. 6 shows a diagram of a memory apparatus of an embodiment of the invention.

FIG. 7A and FIG. 7B respectively show schematics of different embodiments of an operation circuit.

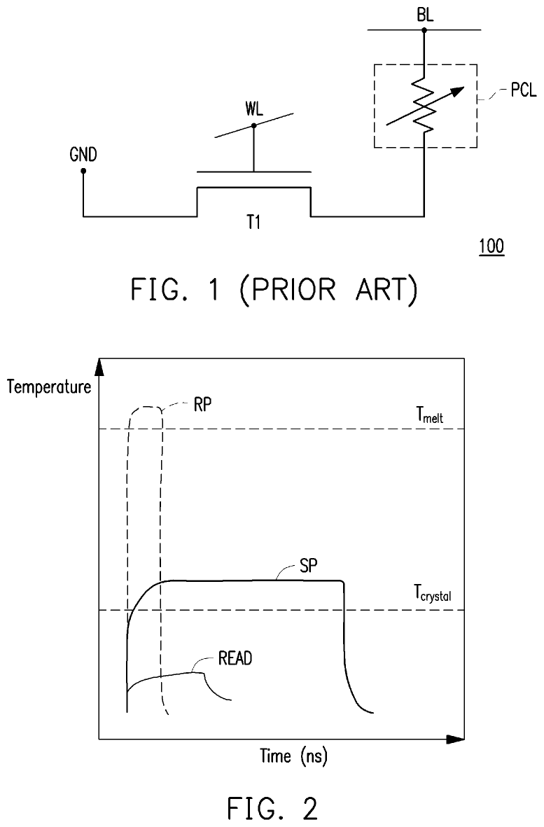

### DESCRIPTION OF THE EMBODIMENTS

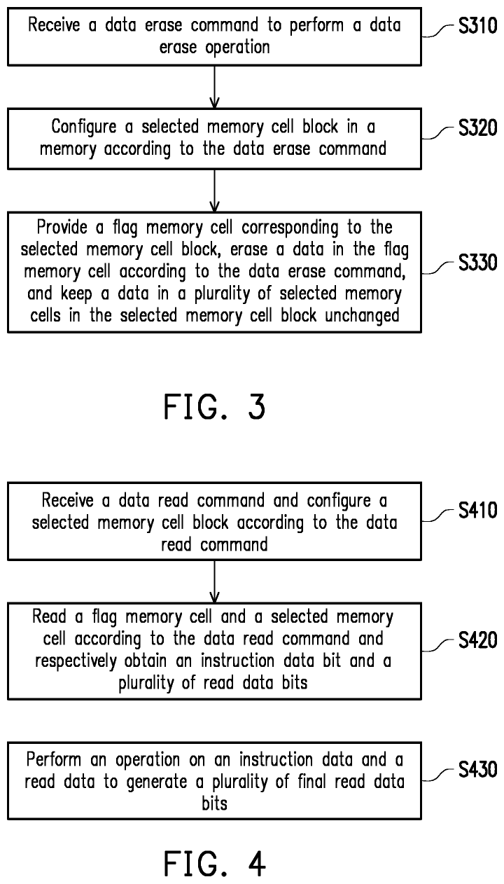

Please refer to FIG. 3. FIG. 3 shows a flowchart of a data access method of a memory of an embodiment of the invention. The memory of the present embodiment may be a resistive memory cell, a flash memory cell, a phase change memory cell, or any other form of non-volatile memory cells. In step S310, a data erase command is received to perform a data erase operation. Here, the data erase operation may be a reset operation performed for the memory cell. In the data erase operation, in step S320, a selected memory cell block in the memory is set according to the data erase command, and in step S330, a flag memory cell corresponding to the selected memory cell block is provided, a data in the flag memory cell is erased according to the data erase command, and a data in the plurality of selected memory cells in the selected memory cell block is kept unchanged. In particular, the data erase command has an address information. In step S320, the selected memory cell block in the memory is set according to an address information in the data erase command.

Next, in step S330, a flag memory cell corresponding to the selected memory cell block is provided, and when the erase operation is performed for the selected memory cell block, in step S330, a physical erase operation is performed only for the flag memory cell, and the physical erase operation is not performed for a plurality of selected memory cells in the selected memory cell block, and a data in the selected memory cells is kept unchanged.

As may be seen from the above description, in the present embodiment, when an erase operation is performed for a plurality of selected memory cells in the selected memory cell block, a physical erase operation only needs to be performed for a single flag memory cell, and a physical erase operation does not need to be performed for all of the selected memory cells in the selected memory cell block. It takes 100 nanoseconds to perform a physical erase operation (reset operation) for a single memory cell, and a single flag memory cell corresponds to a selected memory cell block with 4K bits, for example. When a comprehensive erase operation is performed for memories respectively with 4K bits, 32K bits, and 64K bits, the time required for the practice of the present embodiment and the conventional method may be as shown in Table 1 below:

TABLE 1

| | 4K bit | 32K bit | 64K bit |
|---|---|---|---|
| Present | 0.1 micro- | 0.8 micro- | 1.6 micro- |
| embodiment | seconds | seconds | seconds |
| Prior art | 409.6 micro- | 3276.8 micro- | 6553.6 micro- |
| | seconds | seconds | seconds |

As is clear from Table 1, the time required for the memory to perform the erase operation may be greatly reduced by the method of an embodiment of the invention.

Referring to FIG. 4, FIG. 4 shows a flowchart of a data access method for a memory of another embodiment of the invention. When a data reading operation is performed, in step S410, a data read command is received and a selected memory cell block is set according to the data read command. Next, in step S420, a reading operation is performed on the flag memory cell corresponding to the selected memory cell block and the selected memory cells in the selected memory cell block according to the data read command, and an instruction data bit and a plurality of read data bits are respectively obtained. In step S430, an operation is performed on the instruction data bit and the read data bits to generate a plurality of final read data bits.

In detail, step S420 is used to obtain the instruction data bit recorded in the flag memory cell corresponding to the read selected memory cell block. In particular, the instruction data bit may be used to instruct whether the corresponding elected memory cell block is in an erased state. For example, when the selected memory block is in the erased state, the instruction data bit may be a first logic level. In contrast, when the selected memory block is in a non-erased state, the instruction data bit may be a second logic level, wherein the first logic level and the second logic level are complementary. In step S430, an operation (for example, a logic operation) with each of the read data bits may be performed via the instruction data bit, the read data bits are masked when the instruction data bit is the first logic level, and all of the final read data bits are changed to the erased state. In contrast, when the instruction data bit is the second logic level, the final read data bits are made the same as the read data bits.

In the present embodiment, the first logic level may be logic 1, the second level may be logic 0, and the logic operation may be a logic OR operation. In another embodiment of the invention, the first logic level may be logic 0, the second level may be logic 1, and the logic operation may be a logic AND operation.

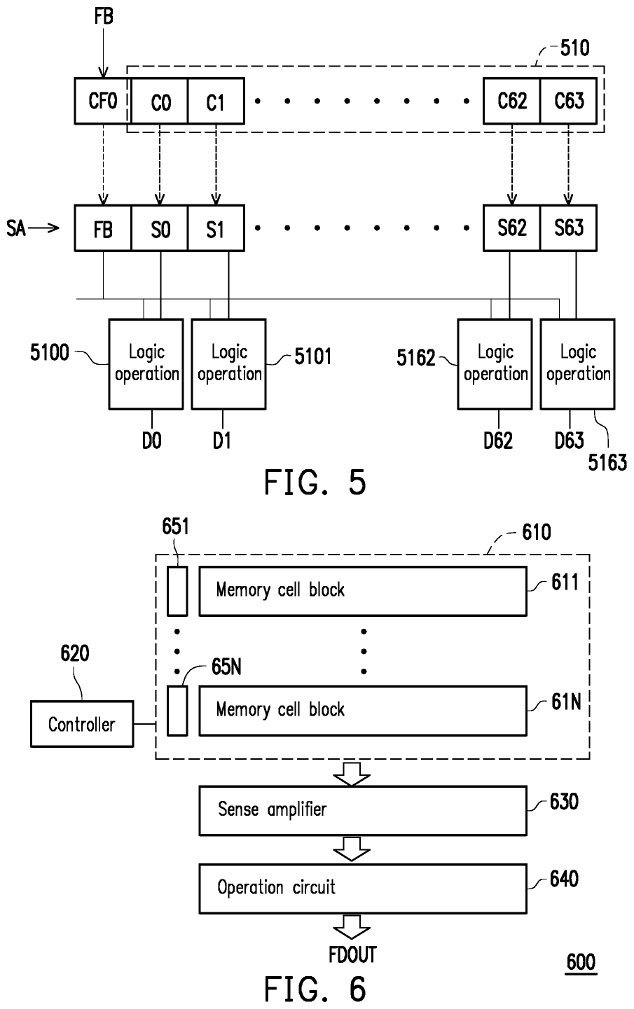

Referring to FIG. 5 below, FIG. 5 shows a schematic of an operation of a data access method of an embodiment of the invention. In FIG. 5, when an erase operation is performed on a selected memory cell block 510, it is not necessary to perform the erase operation for any of selected memory cells C0 to C63 in the selected memory cell block 510, and the erase operation only needs to be performed for a flag memory cell CF0 corresponding to the selected memory cell block 510, and the flag memory cell CF0 records the selected memory cell block 510 as an instruction data bit FB in an erased state. During a data reading operation, a data sensing operation is performed for the flag memory cell CF0 and the selected memory cells C0 to C63 via a sense amplifier SA, and the instruction data bit FB and read data bits S0 to S63 may be respectively obtained. Then, via logic operations 5100 to 5163, a logic operation may be respectively performed on the instruction data bit FB and the read data bits S0 to S63 to generate final read data bits D0 to D63.

In the present embodiment, the flag memory cell CF0 may be disposed in the selected memory cell block 510, or may be disposed at any position outside the selected memory cell block 510 without specific limitation. The flag memory cell CF0 is disposed in the memory and has the same hardware architecture as any of the selected memory cells C0 to C63.

In addition, the selected memory cell block 510 of the present embodiment has a selected memory cell of 64 bits, which is merely an illustrative example. The number of bits included in the selected memory block 510 may be determined by the designer without limitation.

Referring to FIG. 6, FIG. 6 shows a schematic of a memory apparatus of an embodiment of the invention. A memory apparatus 600 includes a memory cell array 610, a controller 620, a sense amplifier 630, and an operation circuit 640. The memory cell array 610 has a plurality of memory cell blocks 611 to 61N and flag memory cells 651 to 65N respectively corresponding to the memory cell blocks 611 to 61N. The controller 620 is coupled to the memory cell array 610 and performs a data erase operation for at least one of the memory cell blocks 611 to 61N by performing the action flow shown in FIG. 3. The sense amplifier 630 is coupled to the memory cell array 610 and the operation circuit 640. When the data reading operation flow shown in FIG. 4 is performed, the controller 620 may perform a data reading operation in conjunction with the sense amplifier 630 and the operation circuit 640 to obtain a final read data FDOUT.

In the present embodiment, the memory cell array 610 may be formed by a resistive memory cell, a flash memory cell, a phase change memory cell, or any other form of non-volatile memory cell. The controller 620 may be designed by a hardware description language (HDL) or any other design methods of a digital circuit known to those having ordinary skill in the art, and is a hardware circuit implemented by a field programmable gate array (FPGA), complex programmable logic device (CPLD), or application-specific integrated circuit (ASIC). The sense amplifier 630 may then be constructed using any sense amplifier known to those having ordinary skill in the art without specific limitation.

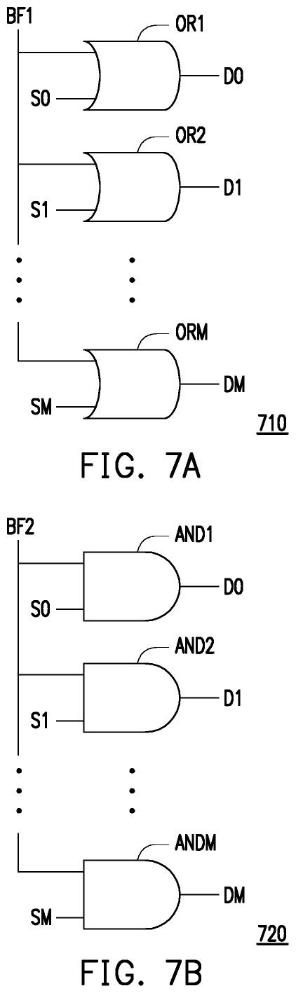

For details of the implementation of the operation circuit 640, please refer to the schematics of different embodiments of the operation circuit respectively shown in FIG. 7A and FIG. 7B. In FIG. 7A, an operation circuit 710 includes a plurality of OR gates OR1 to ORM.

The OR gates OR1 to ORM respectively receive a plurality of read data S0 to SM and collectively receive an instruction data bit BF1. The OR gates OR1 to ORM also respectively generate a plurality of final read data bits D0 to DM. In the present embodiment, when the memory cell block corresponding to the instruction data bit BF1 is in the erased state, the instruction data bit BF1 is logic 1. In this case, the OR gates OR1 to ORM mask the read data S0 to SM according to the instruction data bit BF1 and change all of the final read data bits D0 to DM to logic 1 (erased state). In contrast, when the memory cell block corresponding to the instruction data bit BF1 is in the non-erased state, the instruction data bit BF1 is logic 0. In this case, the OR gates OR1 to ORM respectively transmit the read data S0 to SM to generate the final read data bits D0 to DM. That is to say, the read data S0 to SM are respectively equal to the final read data bits D0 to DM.

In FIG. 7B, an operation circuit 720 includes a plurality of AND gates AND1 to ANDM. The AND gates AND1 to ANDM respectively receive a plurality of read data S0 to SM and collectively receive an instruction data bit BF2. The AND gates AND1 to ANDM also respectively generate the plurality of final read data bits D0 to DM. In the present embodiment, when the memory cell block corresponding to the instruction data bit BF2 is in the erased state, the instruction data bit BF2 is logic 0. In this case, the AND gates AND1 to ANDM mask the read data S0 to SM according to the instruction data bit BF2 and change all of the final read data bits D0 to DM to logic 0 (erased state). In contrast, when the memory cell block corresponding to the instruction data bit BF2 is in the non-erased state, the instruction data bit BF2 is logic 1. In this case, the AND gates AND1 to ANDM respectively transmit the read data S0 to SM to generate the final read data bits D0 to DM. That is to say, the read data S0 to SM are respectively equal to the final read data bits D0 to DM.

Based on the above, in the invention, a flag memory cell is disposed corresponding to each memory cell block, and the erased state of the corresponding memory cell block is recorded via the flag memory cell. In this way, when the selected memory cell block is erased, an erase operation may be performed only for the corresponding flag memory cell, thereby effectively saving the time taken by the memory cell erase operation and improving memory access efficiency. Moreover, in an embodiment of the invention, the number of times the memory cell is physically erased may be reduced, thus increasing the life of the memory.

Although the invention has been described with reference to the above embodiments, it will be apparent to one of ordinary skill in the art that modifications to the described embodiments may be made without departing from the spirit of the invention. Accordingly, the scope of the invention is defined by the attached claims not by the above detailed descriptions.

1. A data access method for a memory, comprising:
receiving a data erase command to perform a data erase operation; and
during the data erase operation:
setting a selected memory cell block to be erased in the memory according to the data erase command; and
providing a flag memory cell corresponding to the selected memory cell block, erasing a data in the flag memory cell according to the data erase command, and keeping a data in a plurality of selected memory cells in the selected memory cell block unchanged.

2. The data access method for the memory of claim 1, further comprising:
receiving a data read command and setting the selected memory cell block according to the data read command;
reading the flag memory cell and the selected memory cells according to the data read command and respectively obtaining an instruction data bit and a plurality of read data bits; and
performing an operation on the instruction data and the read data bits to generate a plurality of final read data bits.

3. The data access method of claim 2, wherein the step of performing the operation on the instruction data bit and the read data bits to generate the final read data bits comprises:
mask the read data bits by the instruction data bit to set all of the final read data bits to an erased state when the instruction data bit is in the erased state; and
make the final read data bits respectively the same as the read data bits by the instruction data bit when the instruction data bit is in a non-erased state.

4. The data access method of claim 3, wherein the operation is a logic operation.

5. The data access method of claim 4, wherein when the erased state is logic 1, the logic operation is a logic OR operation; and when the erased state is logic 0, the logic operation is a logic AND operation.

6. A memory apparatus, comprising:
a plurality of memory cell blocks;
a plurality of flag memory cells respectively corresponding to the memory cell blocks;
a controller coupled to the memory cell blocks and the flag memory cells and configured to:
receive a data erase command to perform a data erase operation; and
set a selected memory cell block to be erased in the memory cell blocks according to the data erase command during the data erase operation; and
erase a data in a flag memory cell corresponding to the selected memory cell block according to the data erase command and keep a data in a plurality of selected memory cells in the selected memory cell block unchanged.

7. The memory apparatus of claim 6, wherein the controller is further configured to:
receive a data read command and set the selected memory cell block according to the data read command.

8. The memory apparatus of claim 6, further comprising:
a sensing amplifier circuit coupled to the selected memory cell block and the corresponding flag memory cell and configured to sense a data of the selected memory cell block and the corresponding flag memory cell to respectively obtain an instruction data bit and a plurality of read data bits; and
an operation circuit coupled to the sensing amplifier circuit to perform an operation on the instruction data and the read data bits to generate a plurality of final read data bits.

9. The memory apparatus of claim 8, wherein the operation circuit is configured to:
mask the read data bits by the instruction data bit to set all of the final read data bits to an erased state when the instruction data bit is in the erased state; and
make the final read data bits respectively the same as the read data bits by the instruction data bit when the instruction data bit is in a non-erased state.

10. The memory apparatus of claim 8, wherein the operation circuit comprises a plurality of logic gates, and when the erased state is logic 1, each of the logic gates is an OR logic; when the erased state is logic 0, each of the logic gates is an AND logic gate.
